(19) United States
(12) Patent Application Publication
(10) Pub. No.: US 2015/0060113 A1
(43) Pub. Date: Mar. 5, 2015

(54) PHOTOCURABLE COMPOSITION, ARTICLE, AND METHOD OF USE

(71) Applicants: Yongcai Wang, Rochester, NY (US); John Andrew Lebens, Rush, NY (US); John DiCillo, Rochester, NY (US)

(72) Inventors: Yongcai Wang, Rochester, NY (US); John Andrew Lebens, Rush, NY (US); John DiCillo, Rochester, NY (US)

(21) Appl. No.: 14/017,707

(22) Filed: Sep. 4, 2013

(51) Int. Cl. C08G 59/02; H05K 1/09; B29C 59/00; H05K 1/02; C08L 63/00; H01B 1/20

(52) U.S. Cl. CPC C08G 59/02; C08L 63/00; H01B 1/20; B29C 59/00; H05K 1/0296; H05K 1/097; C08L 2203/20; B29K 2063/00
USPC 174/253; 528/27; 522/170; 524/868; 252/500; 264/446; 428/447; 428/221; 428/195.1

(57) ABSTRACT

A photocurable composition includes an acid-generating compound, a multifunctional epoxy resin, and an epoxysilane oligomer represented by the following Structure (I):

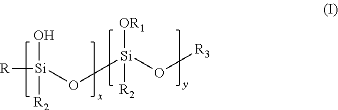

wherein R₁ is a substituted or unsubstituted alkyl group, R₂ is a substituted or unsubstituted linear, branched, or cyclic alkyl group or an alkyl ether residue substituted with an epoxide, R₃ is hydrogen or a substituted or unsubstituted alkyl, and x+y≧2. The photocurable composition can be provided as a photoresist layer on a substrate, and can then be imprinted to form a pattern of micro-channels. These micro-channels can be filled with a conductive composition (ink) and used to form an entrenched pattern of micro-wires to provide a transparent conductive electrode.

### CROSS REFERENCE TO RELATED APPLICATIONS

Reference is made to commonly assigned, co-pending U.S. patent application Ser. No. ______ (Attorney Docket K001521) filed concurrently herewith by Wang, Lebens, and Wright and entitled “METHOD OF FORMING CONDUCTIVE FILMS WITH MICRO-WIRES,” the disclosure of which is incorporated herein by reference.

Reference is also made to the following commonly assigned and copending patent applications:

U.S. Ser. No. 13/746,346 filed Jan. 22, 2013 by Lebens et al.;

U.S. Ser. No. 13/746,352 filed Jan. 22, 2013 by Lebens et al.;

U.S. Ser. No. 13/757,891 filed Feb. 4, 2013 by Wang et al.;

U.S. Ser. No. 13/757,896 filed Feb. 4, 2013 by Wang et al.;

U.S. Ser. No. 13/757,899 filed Feb. 4, 2013 by Wang et al.;

U.S. Ser. No. 13/757,901 filed Feb. 4, 2013 by Wang et al.;

U.S. Ser. No. 13/757,905 filed Feb. 4, 2013 by Wang et al.; and

U.S. Ser. No. 13,757,913 filed Feb. 4, 2013 by Wang et al.;

the disclosures of all of which are incorporated herein by reference.

### FIELD OF THE INVENTION

This invention relates to a photocurable composition that can be incorporated into a photocurable article that can be used for providing photoresist layers useful for forming patterns of micro-channels. Such micro-channels can be filled with a conductive composition (“ink”) to form a conductive pattern. More particular, the present invention relates to a photocurable composition that can be used to form high quality surface patterns by photo-imprint lithography. This photocurable composition exhibits improved surface properties after curing and can be wetted more readily with aqueous conductive inks having a high surface tension.

### BACKGROUND OF THE INVENTION

Radiation curable (or photocurable) compositions are known for use in microelectronic and microfluidic devices. Using such devices, photoimaging or photopatterning can be accomplished by exposing the photocurable composition on a suitable substrate to a photomask that induces a solubility change in the photocurable composition such that the exposed or non-exposed areas can be selectively removed by treatment with a developer solution.

More recently, imprinting techniques have been proposed as one of the methods for forming micrometer and sub-micrometer sized features on a substrate. In such processes, patterns are formed by pressing a stamp or mold, which has a preformed pattern on its surface, against a substrate having a suitable impressionable receiving layer. Both thermoplastic resins or photocurable resins can be used as the impressionable receiving layer. A thermoplastic resin can be heated above its softening point before imprinting and subsequently cooled to lower temperatures below the softening point to cause the pattern to be fixed on the impressionable receiver surface before the stamp or mold is released. With photocurable resins, the stamp or mold is pressed against the impressionable receiver surface during photoexposure (for example during photoimprint lithography). The pattern is fixed mostly by the photocuring. Depending upon the nature of the photocurable resin used, an additional thermal curing can be used before the stamp or mold is released.

Photocurable compositions comprising a highly branched, multifunctional epoxy bisphenol A-novolac resin, such as Epon SU-8 (Momentive Specialty Chemicals Inc.) have been described as useful in high aspect photoresists having thick photocurable layers. Such photocurable compositions are generally formulated as solutions including a photoacid generating compound such as a di- or triaryl-substituted sulfonium or iodonium complex salt (or other onium salt). The photocurable compositions can be applied to a substrate and dried to provide a dry coating thickness of up to 100 μM. The dried coating can be photoimaged by exposure to UV light through a patterned photomask using contact, proximity, or projection exposures and then developed to form a high resolution, negative tone relief image of the photomask. Other performance benefits with the use of the Epon SU-8 resin are its excellent thermal, chemical, and etching resistances when it is cured properly.

Uncured Epon SU-8 resin has a relatively low glass transition temperature of about 60° C. It is also known as a monomeric glass material so it has excellent flow properties. It is therefore a natural candidate for photoimprint lithography. However, it still requires a relatively high temperature (about 100° C.) for short imprint times and short photocuring cycles. Lower imprint temperatures (for example 60° C.) require significantly higher pressures and longer times for proper material flow. Imprinting under such conditions, although useful for certain applications on rigid substrates such as glass and silicone wafers, is not very suitable for imprinting on flexible substrates such as polyesters and polycarbonates where heat distortion becomes a significant concern in order to achieve better layer-over-layer overlay accuracy or lower thermal residual stress.

MicroChem Corp. has developed a product called XP SU-8 4000 NPG using a blend of epoxy resins to exhibit a lower glass transition temperature (T_{g}) for better imprinting properties (see for example, “Nanoimprinting with SU-8 Epoxy Resists” by Donald W. Johnson et al, Singapore Nanoimprint Symposium, 2007). This product still requires a pressing pressure of above 20 bar (2 megaPascals) to generate a defect-free pattern having good uniformity. However, this pressing pressure is still too high to make a large imprint with good uniformity particularly on a flexible substrate.

U.S. Patent Application Publication 2011/0254191 (Takeuchi) describes a film-forming composition for imprinting containing a siloxane resin and an organic solvent that includes a particular solvent having a boiling point of 100-200° C. This film-forming composition can be imprinted at room temperature and lower pressing pressure (for example, 1 to 50 megaPascals).

It is therefore desirable to have an improved photocurable composition that has the performance characteristics of a photocurable composition comprising the Epon SU-8 resin but at the same time exhibits improved process latitude including, for example, lower material flow temperatures, short imprint and photocuring cycles, and lower photoimprint lithography pressing pressures.

Recently, transparent electrodes comprising very fine patterns of conductive micro-wires have been proposed for various uses including touch screen displays. For example, capacitive touch screens displays having mesh electrodes including very fine line patterns of conductive elements, such as metal wires or conductive traces, are described in U.S. Patent Application Publication 2010/0328248 (Mozdzyn) and U.S. Pat. No. 8,179,381 (Frey et al.), the disclosures of which are hereby incorporated in by reference. As disclosed in U.S. Pat. No. 8,179,381, fine conductor patterns can be made by using one of several processes, including laser-cured masking, inkjet printing, gravure printing, micro-replication, and micro-contact printing. The transparent micro-wire patterns can include micro-wires that are 0.5 μm to 4 μm wide and exhibit a transparency in the display of 86% to 96%.

It is a natural extension of photoimprint lithography to form patterns comprising conductive micro-wires by imprinting micro-channels in a suitable imprintable substrate, filling the micro-channels with a conductive composition (ink), removing the excess conductive composition from between micro-channels, curing the conductive compositions within the micro-channels, and polishing or buffering the substrate surface to improve the optical properties of the resulting display such as haze and transparency. The main challenge when using such a method is completely filling the micro-channels with the conductive composition without retaining any residual conductive composition between the micro-channels.

Good adhesion of the micro-wires in the micro-channels is required for flexible electronics such as touch screen displays as such displays can potentially undergo a great deal of bending during their assembly into various electronic devices. Weak adhesion can cause the micro-wires to pop out of the micro-channels and break. This is an obvious problem that will damage the usefulness of the display devices. There is a desire, then, to be able to form conductive micro-wires using photoimprint lithography that exhibit improved adhesion in the micro-channels, and that are protected against scratches and other potential physical damage.

### SUMMARY OF THE INVENTION

The present invention provides a photocurable composition comprising:

a compound that generates an acid upon exposure to radiation of at least 190 nm and up to and including 500 nm,

a multifunctional epoxy compound having an epoxy equivalent molecular weight of less than 1,000, and

an epoxysilane oligomer that is represented by the following Structure (I):

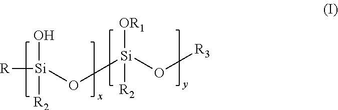

wherein R and R₁ are independently substituted or unsubstituted alkyl groups, R₂ is a substituted or unsubstituted linear, branched, or cyclic alkyl group or an alkyl ether residue substituted with an epoxide, R₃ is hydrogen or a substituted or unsubstituted alkyl, and x+y≧2.

Other embodiments of this invention include a photocurable article comprising a substrate and having thereon a dry photocurable layer comprising the photocurable composition of any embodiment of this invention.

Moreover, this invention also provides a method for forming a conductive element, the method comprising:

providing the photocurable article of any embodiment of this invention,

forming a pattern of micro-channels within the photocurable composition of the photocurable article, and

exposing the photocurable composition to form a patterned article comprising a pattern of cured micro-channels.

In some embodiments, this method further comprises:

filling the pattern of cured micro-channels with a conductive composition to form a pattern of conductive micro-wires.

Thus, the method of this invention can be used to provide a patterned article comprising a pattern of cured micro-channels.

In addition, the method of this invention can be used to provide an electrically conductive article comprising a pattern of conductive micro-wires provided by the method of any embodiment of this invention.

Thus, some embodiments of the invention provide photoresist layers comprising the photocurable composition of the present invention applied over a suitable substrate especially a flexible substrate. Such photoresist layers are useful for photoimprint lithography with improved processing latitude such as lower imprinting temperature, lower compression pressure, and shorter imprint and curing cycles. The photoresist layers are particularly useful when the substrate is a flexible plastic (or polymeric) substrate since it reduces any significant amount of heat distortion and build-up of residual strength from the imprinting process. The photocured composition of the present invention exhibits excellent heat resistance, good chemical stability, and excellent scratch resistance. It is particularly useful that the substrate to which the photocurable composition is transparent.

Thus, the present invention can provide a conductive electrode comprising patterns of very fine conductive micro-wires entrenched in micro-channels on a substrate, wherein the micro-channels comprise a photocured product of the photocurable composition of the present invention and the conductive micro-wires are a photocured product of conductive metal nanoparticles. In particularly useful embodiments, the conductive electrode is a transparent conductive electrode comprising patterns of very fine conductive micro-wires entrenched in the micro-channels on a transparent substrate.

A significant advantage of the present invention is that transparent conductive electrodes exhibit very low distortion and good uniformity when they comprise flexible substrates, excellent optical properties (low surface haze and high % light transmission), and exceptional low electrical resistivity of less than 10 ohms/sq with the micro-wires having widths as narrow as 2 to 3 μm. Such transparent conductive electrodes of the present invention can be used to form large touch panel displays especially on transparent flexible substrates that exhibit improved high frequency response.

### BRIEF DESCRIPTION OF THE FIGURES

FIG. 1 is a mold surface pattern that is used to prepare photo-imprints in the Control and Invention Examples 1-3 articles described below.

FIGS. 2a through 2d are photomicrographs obtained using an optical microscopy showing the imprinted patterns in photocured layers for the Control and Invention Examples 1-3 described below.

FIG. 3 is a scanning electron micrograph of conductive micro-wires obtained in the Invention Examples described below.

### DETAILED DESCRIPTION OF THE INVENTION

### Definitions

As used herein to define various components of the photocurable composition, conductive layers, and formulations, unless otherwise indicated, the singular forms “a”, “an”, and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term's definition should be taken from a standard dictionary.

The use of numerical values in the various ranges specified herein, unless otherwise expressly indicated otherwise, are considered to be approximations as though the minimum and maximum values within the stated ranges were both preceded by the word “about”. In this manner, slight variations above and below the stated ranges can be used to achieve substantially the same results as the values within the ranges. In addition, the disclosure of these ranges is intended as a continuous range including every value between the minimum and maximum values.

The term “imprinting” used herein to form the micro-channels in a photocurable composition of the present invention can also be known as “embossing” or “impressing”.

A “micro-channel” is a groove, trench, or channel formed on or in a substrate as described below and generally includes an average depth and average width in micrometers.

### Photocurable Compositions

The photocurable compositions of this invention comprise three essential components to provide the desired effects necessary to prepare electrically conductive articles, such as conductive electrode arrays. These three essential components are a compound that generates acid upon exposure to radiation of at least 190 nm and up to and including 500 nm, a multifunctional epoxy compound having an epoxy equivalent molecular weight of less than 1,000, and an epoxysilane oligomer, all defined below.

In general, the photocurable composition has a haze value of less than 10% and more typically less than 2%, as determined by spectrophotometry and known procedures.

Moreover, the photocurable composition generally has a light transmission of at least 85% and typically of at least 90% as determined by spectrophotometry and known procedures.

It would be clear to one of ordinary skill in the art that the specified values provided above can be changed depending upon any additional additives that are incorporated into the photocurable compositions. For example, a matting agent can be added to the photocurable composition to improve transport properties but the matting agent can increase haze. A colorant can also be added to the photocurable composition to improve the appearance of the final article but the presence of a colorant can reduce light transmission. Thus, the desired properties are balanced with the incorporation of various additives.

The photocurable composition is particularly useful for preparing electrically conductive layers, wires, and patches that have low electrical resistivity of less than 10 ohms/square, particularly if the electrically conductive wires have an average width of at least 2 to 3 μm. These electrically conductive wires can be incorporated on transparent substrates into transparent devices such as touch screen devices that exhibit high frequency response.

In many embodiments of the photocurable composition, the multifunctional epoxy compound (described below) has a softening point of 20° C. or greater, and the epoxysilane oligomer (described below) has a softening point less than 20° C.

One essential component of the photocurable compositions of this invention is a compound (or mixture thereof) that provides or generates an acid having a pKa of less than 2 or typically a pKa less than 0 during exposure to radiation having a λₘₐₓ of at least 190 nm and up to and including 500 nm, or typically radiation having a λₘₐₓ of at least 250 nm and up to and including 450 nm to initiate reaction with epoxy groups.

Particularly useful such acid-generating compounds are onium salts that decompose upon irradiation. An onium salt (also known as an onium compound) is a compound that is formed by the attachment of a proton to a mononuclear parent hydride of a Group 15 element (for example nitrogen and phosphorus), a chalcogen of Group 16 (for example sulfur and selenium), or a halogen (such as fluorine, chlorine, and iodine). Particularly useful onium salts include but are not limited to, sulfonium salts, phosphonium salts, iodonium salts, aryldiazonium salts, hydroxyimide sulfonates, hydroxyimino sulfonates, and nitrobenzyl sulfonate esters. The sulfonium salts, phosphonium salts, and iodonium salts are particularly useful, including but not limited to arylsulfonium salts and aryliodonium salts. Useful onium salts have substituted aryl groups and strong acid anions such as hexafluorophosphate, tetrafluoroborate, hexofluoroarsenate, and hexafluoroantimonate. Representative examples of useful onium salts are triphenyl sulfonium triflate, trifluoromethylsulfonic acid, and bis(4-t-butylphenyl) iodonium triflate. Other useful onium salts are described for example in U.S. Pat. No. 4,210,449 (Schlesinger et al.), U.S. Pat. No. 4,273,668 (Crivello), and U.S. Pat. No. 4,491,628 (Frechet et al.), the disclosures of which are incorporated herein by reference with respect to the onium salts.

More particularly, the acid generating compound is an onium salt of a Group V-A element, an onium salt of a Group VI-A element, or an aromatic halonium salt. Examples of triaryl-substituted sulfonium complex salts useful as acid-generating compounds include but are not limited to, triphenylsulfonium tetrafluoroborate, triphenylsulfonium hexafluorophosphate, triphenylsulfonium hexafluoroantimonate, tritolylsulfonium hexafluorophosphate, anisyldiphenylsulfonium hexafluoroantimonate, 4-butoxyphenyldiphenyl-sulfonium tetrafluoroborate, 4-chlorophenyldiphenylsulfonium hexafluoroantimonate, 4-acetoxy-phenyldiphenylsulfonium tetrafluoroborate, 4-acetamidophenyldiphenylsulfonium tetrafluoroborate, 4-[4-(2-chlorobenzoyl)-phenylthio]phenylbis(4-fluorophenyl)sulfonium hexafluoroantimonate (Adeka Optmer SP-172 by Asahi Denka Kogyo KK).

Examples of aryl-substituted iodonium complex salt acid-generating compounds include but are not limited to, diphenyliodonium trifluoromethanesulfonate, (p-t-butoxyphenyl)phenyliodonium trifluoromethanesulfonate, diphenyliodonium p-toluenesulfonate, (p-t-butoxyphenyl)-phenyliodonium p-toluenesulfonate, bis(4-t-butylphenyl)iodonium hexafluorophosphate, and diphenyliodonium hexafluoroantimonate.

While the onium salts are particularly useful in the practice of this invention, other acid-generating compounds include but are not limited to, nitrobenzyl esters as described for example in U.S. Pat. No. 5,200,544 (Houlihan et al.) and oximes of sulfonates as described in U.S. Pat. No. 7,749,677 (Ando), the disclosures of which are incorporated herein by reference.

One or more compounds that generate the desired acid(s) are generally present in the photocurable composition (and dry photocurable layer) in an amount of at least 0.1 weight % and up to and including 20 weight %, or more likely at least 1 weight % and up to and including 10 weight %, based on the total photocurable composition solids (or dry photocurable layer weight).

A second essential component of the photocurable composition of this invention is a multifunctional epoxy compound (or mixture thereof). The multifunctional epoxy compounds used in the present invention generally have an epoxy equivalent molecular weight of less than 1000, and more likely less than 500. Thus, these compounds contain a sufficient number of epoxy groups in one molecule for efficient curing reactions with the acid-generating compounds described above. In addition, the multifunctional epoxy compound can have a molecular weight of at least 2,000 and up to and including 11,000, or more likely at least 2,000 and up to and including 8,000, as determined by size exclusion chromatography.

Moreover, the multifunctional epoxy compound has a softening point of 20° C. or more.

Examples of useful multifunctional epoxy compounds include but are not limited to, phenol novolak epoxy resins, a-cresol novolak epoxy resins, triphenyl novolak epoxy resins, and bisphenol A novolak epoxy resins. The multifunctional Bisphenol A novolak epoxy resins are particularly useful, having a functionality of 5 or more. Commercial examples of useful multifunctional epoxy compounds are available as Epicoat 157 from Japan Epoxy Resin Co., Ltd. (Japan), Epiclon N-885 from Dainippon Ink and Chemicals Inc. (Japan), and Epon SU-8 from (Momentive Specialty Chemicals Inc.).

The amount of one or more multifunctional epoxy compounds used in the photocurable composition (and coated layers) is at least 10 weight % and up to and including 90 weight %, or typically at least 30 weight % and up to and including 90 weight % based on total photocurable composition solids.

In some embodiments, the photocurable composition of the present invention comprises a multifunctional epoxy compound that is represented by the following Structure (II):

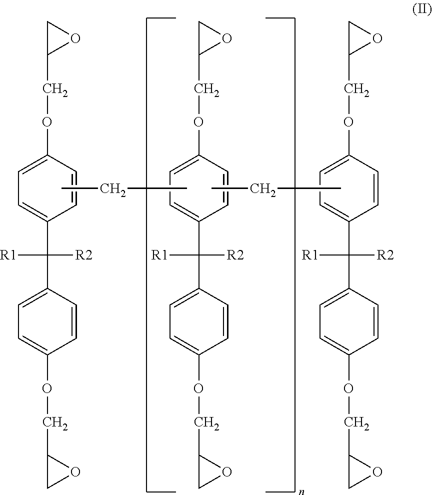

wherein R1 and R2 are independently hydrogen or methyl, and n is 0 or a positive integer, such as at least 1 and more likely at least 3.

The third essential component of the photocurable composition is an epoxysilane oligomer (or mixture thereof). The useful epoxysilane oligomers can be represented by the following Structure (I):

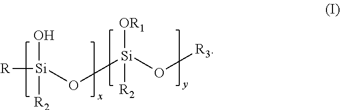

In Structure (I), R and R₁ are independently substituted or unsubstituted alkyl groups having 1 and up to and including 10 carbon atoms (both linear and branched groups) and including aryl-substituted alkyl (arylalkyl) groups. In particular R and R₁ are independently substituted or unsubstituted arylalkyl groups having at least 7 carbon atoms such as substituted or unsubstituted benzyl groups.

R₂ is a substituted or unsubstituted linear, branched, or cyclic alkyl group having up to and including 30 carbon atoms or an alkyl ether residue substituted with an epoxide

R₃ is hydrogen or a substituted or unsubstituted alkyl (linear or branched groups, including cyclic alkyl groups) or an unsubstituted arylalkyl group, each having up to 10 carbon atoms.

In Structure (I), x+y≧2, or more particularly, the sum of x and y is at least 3.

For example, a useful epoxysilane oligomer can have the general structure represented by the following Structure (III):

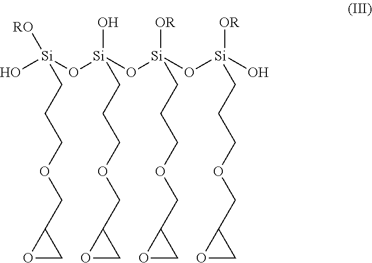

wherein R in Structure (III) is hydrogen or a substituted or unsubstituted alkyl group having 1 to 10 carbon atoms (linear or branched groups). For example, R can be a methyl or ethyl group. The epoxysilane oligomer in Structure (III), or any of the compounds described herein, can be characterized by the alcohol content and epoxy functionality.

The alcohol content of an epoxysilane oligomer can be measured by hydrolysis in water followed by gas chromatography to determine the amount of methanol liberated (methanol released). The epoxy functionality can be expressed in terms of meq/gram or epoxy equivalent weight.

A useful epoxysilane oligomer that is commercially available is Coatosil MP200 silane (available from Momentive Performance Materials Inc.), which epoxysilane oligomer has an alcohol content of about 22% and epoxy content of about 4.785 meq/gram. It is also possible that the epoxysilane oligomer have a softening point less than or equal to 20° C.

One or more epoxysilane oligomers are present in the photocurable composition (and coated layers) in an amount of at least 10 weight % and up to and including 90 weight %, or typically at least 10 weight % and up to and including 70 weight %, based on total photocurable composition total solids.

In addition, the multifunctional epoxy compound to the epoxysilane oligomer weight ratio can be from 9:1 and to and including 1:9.

While not essential to the photocurable compositions of this invention, the photocurable compositions can also comprise one or more photo sensitizers that can enhance sensitivity to the radiation used to initiate curing. A variety of photosensitizers are known in the art such as aromatic tertiary amines, aromatic tertiary diamines and certain aromatic polycyclic compounds such as substituted or unsubstituted anthracene compounds, as described for example in U.S. Pat. No. 4,069,054 (Smith) and U.S. Pat. No. 7,537,452 (Dede et al.), the disclosures of which are incorporated herein by reference. Particularly useful photosensitizers include unsubstituted anthracene and substituted anthracenes such as 9,10-diethoxyanthracene and 2-t-butyl-9,10-diethoxyanthracene. Other useful photosensitizers include but are not limited to, N-alkyl carbazole such as N-ethyl carbazole, N-ethyl-3-formayl carbazole, 1,4,5,8,9-pentamethyl carbazole, and N-ethyl-3,6,dibenzoyl-9-ethylcarbazole. Naphthols can be used as photosensitizers and include but are not limited to, 1-naphthol, β-naphthol, α-naphthol methyl ether, and α-naphthol ethyl ether. Mixtures of photosensitizers can be used if desired.

One or more photosensitizers can be present in the photocurable composition (and coated layers) in an amount of at least 0.1 weight % and up to and including 10 weight %, or more likely at least 0.2 weight % and up to and including 5 weight %, based on the total solids in the photocurable composition (or dry coated layer weight).

The photocurable composition can further comprise one or more of an adhesion promoter, glycidyl ether reactive monomer, filler, lubricant, coating surfactant, matting agent, or conductive particle.

Examples of the useful adhesion promoters include but are not limited to, 3-glycidoxypropyltrimethoxysilane, 3-glycidoxypropyltriethoxysilane, mercaptopropyltrimethoxysilane, vinyltrimethoxysilane, methacryloyloxypropyl trimethoxysilane, and mixtures thereof. Such compounds can be present in an amount of at least 1 weight % and up to and including 10 weight %, based on total photocurable composition solids.

Useful glycidyl ether reactive monomers include but are not limited to, glycidyl ethers with two or more glycidyl ether groups, acyclic epoxy compounds such as 3,4-epoxycyclohexyl methacrylate and 3,4-epoxycyclohexylmethyl-3′4′-epoxycyclohexyl carboxylate. Mixtures of these compounds can be used if possible. Such compounds can be present in an amount of at least 1 weight % and up to and including 10 weight %, based on the total photocurable composition solids.

The photocurable compostion of the invention can further contain fillers, lubricants, coating surfactants, matting agents, and conductive particles. Examples of useful fillers include but are not limited to, colloidal silica, clay, titanium dioxide, and mixtures thereof. Examples of useful lubricants include but are not limited to, wax and wax derivatives, siloxane polymers and copolymers, fluorinated particles such as Teflon, polyolefin particles, and mixtures thereof. Examples of useful surfactants include but are not limited to, fluorinated compounds and siloxane-containing compounds that can modify the surface properties of the photocurable composition in dry form. Examples of useful matting particles include but are not limited to, polymeric and oxide particles of micrometer and submicrometer size. Examples of useful conductive particles include but are not limited to conductive oxides such as antimony doped tino oxide, indium doped tin oxide, conductive polythiophenes, conductive polyanilines, conductive metal particles, and mixtures thereof. All of these additives can be incorporated in amounts that would be readily apparent to one skilled in the art of photocurable compositions.

### Photocurable Articles

The photocurable composition can be formulated using the essential components and optional materials described above, and the formulated photocurable composition can be used to provide a photocurable or photoresist layer applied to a suitable substrate.

A substrate can be formed from a transparent material, metal-containing material, or ceramic material. For example, the substrate can be formed from any useful polymeric, cellulosic, ceramic, or metallic or metal oxide materials. For example, the substrate can be a transparent glass or polymeric material (such as a film) that can include, for example, polyesters such as poly(ethylene terephthalate) and poly(ethylene naphthalate), polycarbonate, polyimides, glass, oxides, metal and metal-modified materials, cellulose triacetate, polystyrene, and others that would be apparent to one skilled in the art. The substrate can also be a multi-layer element or laminate formed from multiple layers of the same or different materials. The substrate can be pretreated before application of the photocurable composition if desired to improve adhesion or other physical or optical properties of the resulting photocurable article.

For example, the substrate can comprise a halogen-containing polymer for example as a coated layer coated on a substrate material. Examples of such polymers include but are not limited to, homopolymers and copolymers derived from vinyl chloride and vinylidene chloride, which copolymers can also include recurring units derived from non-halide containing ethylenically unsaturated polymerizable monomers. These halide-containing polymers can be applied to a substrate material using any suitable technique and for example can be applied as a latex polymer coating. Such a coated polymeric layer can have a dry thickness of up to and including 10 μm.

A useful substrate can have an overall dry thickness of at least 25 μm, and the maximum dry thickness is unlimited and depends upon the end use of the photocurable composition and the resulting photocurable article.

The formed applied photocurable layer on the substrate can have a dry thickness of from 0.1 μm and up to and including 100 μm and this dry thickness can be established for a particular desired use and photocurable article.

The photocurable article can comprise more than one applied photocurable layers, and the multiple photocurable layers can have the same or different compositions and different dry thicknesses.

In many embodiments, it is desired that each applied and dried photocurable layer generally has a softening point at least 40° C.

Depending upon the use of the photocurable article, the photocurable layer can further be overlaid with a protective sheet for easily handling and manipulations for easy and flexible manufacturing.

To formulate a photocurable composition for application to a suitable substrate, one or more organic solvents can be used. Any organic solvent can be used as long as it is capable of dissolving the essential components described above to form a substantially clear solution, and does not result in coating defects such as haze, bubbles, repellency spots, surface roughness, and phase separation. The essential and optional components are dissolved or dispersed within the one or more organic solvents including but not limited to, ketones (such as acetone, 2-butanone, 2-pentanone, 3-pentanone, methyl isobutyl ketone, methyl t-butyl ketone, cyclopentanone, and cyclohexanone), ethers (such as dipropylene glycol dimethyl ether, and dipropylene glycol diethyl ether), tetrahydrofuran, 1,3-dioxolane, 1,4-dioxane, dimethoxyethane, diglyme, triglyme, esters (such as ethyl acetate, propyl acetate, butyl acetate, butyl cellulose acetate, carbitol acetate, propylene glycol monomethyl ether acetate, and gamma-butyrone lactone). Mixtures of these organic solvents can be used if desired. Other useful solvents include those that can be used (mixed) with the organic solvents include alcohols and aromatic and aliphatic hydrocarbons.

The photocurable composition can be applied to a substrate by any suitable coating methods including spin coating, ultrasonic coating, extrusion hopper coating, slide hopper coating, curtain coating, gravure coating, spray coating, air knife coating, and other techniques known in the coating art. The applied photocurable composition can be dried as a uniform layer or patterned layer to form a photocurable or photoresist layer. The photocurable composition solvent(s) can be removed (for example by evaporation) using any suitable drying means.

### Methods for Making Patterned Articles and Electrically Conductive Articles

Using the photocurable compositions and photocurable articles described above, the present invention also provides a method for providing or forming conductive electrodes or conductive elements that can be used in various devices.

The method of this invention can be carried out by forming a pattern of micro-channels using an imprinting mold, which imprinting mold is removed from the pattern of cured micro-channels after the exposing feature and before the filling feature.

Thus, these conductive elements can be provided by forming the photocurable article as described above, and forming a pattern of micro-channels within the photocurable composition of the photocurable article. The photocurable composition can then be imagewise exposed to form a pattern of cured micro-channels in the photocurable article, and the cured micro-channels are filled with a suitable conductive composition, for example comprising conductive metal nanoparticles, to form a pattern of conductive micro-wires. The resulting very fine patterns of conductive micro-wires are entrenched in micro-channels on the substrate.

The substrate is not particularly limited, as described above, and in many embodiments, can be composed of silicone, copper, chromium, iron, aluminum, glass substrate, or a polymer.

A useful method for forming the micro-channels includes applying the photocurable composition of the invention onto a suitable substrate to form a photoresist or photocurable layer, pressing a mold against this photoresist (photocurable) layer, exposing the photoresist (photocurable) layer using a suitable source of curing radiation (such as UV radiation of 150 nm to 450 nm), and releasing the mold from the cured photoresist (photocurable) layer. The exposure can be directed through the substrate or the mold, if either is transparent and radiation transmitting.

The mold can be formed from various suitable materials that would be readily apparent to one skilled in the art. To facilitate exposure through a mold, the mold is composed of fairly transparent materials. For example, the mold can be made of materials including but not limited to, quartz, silicone, organic polymers, siloxane polymers, borosilicates glass, fluorocarbon polymers, cyclic polyolefin, metals, and combinations of these materials.

To facilitate release of the mold from the photocured photoresist layer, the inner mold surface can be treated with a surface modifying agent, which materials are well known in the art. An example of a surface modifying agent is a fluorocarbon silylating agent. The surface modifying agent can be applied, for example, using a plastic surface, a chemical vapor deposition process, a solution treatment, or a vapor treatment involving a solution.

For example, the inner mold surface can comprise a cured silicone including but not limited to a condensation curable silicone, an addition-curable or hydrosilylation-curable silicone, a free radical curable silicone, or a cationic-curable silicone. In some embodiments, the curable silicone can be a photocurable silicone, including UV and visible light curable silicones. In some embodiments, the curable silicone can further comprise reinforcing fillers such as silica or quartz particles. Such cured silicone composition can be typically formed by reacting a multiple ethylenically unsaturated group-containing organo-polysiloxane with an organo-polysiloxane containing a multiplicity of Si-H bonds per molecule. This reaction can be facilitated by the presence of a platinum-containing catalyst.

The mold can be pressed against the photocurable composition of this invention for imprinting using a pressing (imprinting) pressure that can be adjusted depending on the desired imprinting time and temperature. For example, the pressing pressure can be less than 2 megaPascals. The pressing time can vary from a fraction of a second to minutes and the imprinting temperature can be less than 100° C.

In some embodiments, the method can be carried out by forming the pattern of micro-channels using the imprinting mold, which imprinting mold is removed from the pattern of cured micro-channels after the exposing feature and before filling feature with the conductive composition.

In particularly useful embodiments, the conductive element (conductive electrode) is transparent conductive electrode and comprises very fine patterns of conductive micro-wires entrenched in micro-channels on a transparent support that is a polyester composed of poly(ethylene terephthalate) or poly(ethylene naphthalate), polycarbonate, glass, cellulose triacetate, or polystyrene.

The micro-channels prepared according to the present invention can have an average cross-sectional width of 1 nm and up to and including 100 μm microns and an average aspect ratio (width/depth) of greater than 0.1 (measured in at least 10 different locations). For example, the micro-channels can have an average width (as measured in 10 different places) of less than 50 μm and an aspect ratio of greater than 0.2. Thus, the micro-channels have an average width of less than 10 μm and an aspect ratio of less than 10, or an average width of from at least 0.5 μm and up to and including 5 μm and an average aspect ratio of at least 0.1 and up to and including 10, and such micro-channels are formed on a transparent support of a polyester, glass, or polycarbonate. These dimensions can be readily determined using electron microscopy or other images of micro-channels and are usually measured in cross-section that can have various shapes including rounded or squared off shapes, and the walls of the micro-channels can be vertical or sloped to a desired angle from vertical.

The micro-channels formed in accordance with the invention can be filled with a conductive composition (sometimes called an “ink” in the art) comprising a conductive material and a liquid carrier. The liquid carrier is evaporated or removed from the micro-channels, leaving the conductive material therein. Useful conductive materials include but are not limited to, conductive particles such as conductive nanoparticles of conductive metal nanoparticles, a conductive polymer, or a soluble conductive precursor. For example, the conductive material is conductive metal particles and the liquid carrier is water.

Useful conductive compositions can comprise for example, electrically conductive materials that include but are not limited to, conductive polymers, nanoparticles of indium-tin oxide, metals such as gold, silver and silver precursors, copper, and palladium, metal complexes, metal alloys, and combinations thereof. The conductive material can alternatively be a conductive material precursor such as a metal salt (for example a silver salt like a silver halide or an organic silver salt), or an electroless metallization catalyst such as palladium particles.

It is also possible that the conductive materials comprise nanoparticles of electrically conductive materials. Nanoparticles are microscopic particles whose size is measured in nanometers (nm). Nanoparticles include particles having at least one dimension less than 200 nm and in some embodiments, the nanoparticles have an average diameter of at least 3 nm and up to and including 100 nm. The nanoparticles can be in the form of clusters. The shape of the nanoparticles is not limited and includes nanospheres, nanorods, and nanocups. Moreover, the conductive materials also include nanoparticles of carbon such as carbon black, carbon nanotubes, electrically conducting carbon nanotubes, graphene, or carbon black conducting polymers. Metal nanoparticles and dispersions of gold, silver, and copper are also useful in this invention.

For example, in the method of this invention the conductive composition can comprise silver nanoparticles in an amount greater than 10 weight % of the total conductive composition dry weight.

Thus, in many embodiments, the conductive composition used in this invention comprises an electrically conductive material that comprises nanoparticles of an electrically conductive material selected from the group consisting of silver or a silver precursor, gold, copper, palladium, aluminum, titanium, tantalum, indium-tin oxide, or combinations or alloys thereof, for example in the form of nanoparticles. For example, in some very useful embodiments, the conductive composition comprises nanoparticles of an inorganic or organic silver salt such as a silver halide, silver behenate, and other silver salts that would be readily apparent to one skilled in the art.

For example, the conductive composition can comprise nanoparticles of a silver halide (such as silver chloride, silver bromide, silver chlorobromide, or other silver salts of mixed halides).

The conductive compositions can also include various addenda that provide useful properties during formulation, use, or curing, including but not limited to, lubricants, polymer binders such as polymeric latexes and dispersions, solvents, humectants, adhesion promoters, colorants, rheology modifiers, thickeners, crosslinking agents, biological additives, fillers, and non-conductive metal particles in amounts that would be readily apparent to one skilled in the art. For example, the conductive composition can also include a carbon black, dye, or pigment to provide opacity.

Useful conductive compositions comprising metal nanoparticles (such as silver nanoparticles) and specific polymers are described also in copending and commonly assigned U.S. Ser. Nos. 13/757,891; 13/757,896; 13/757,901; 13/757,905; and 757,913 (all filed Feb. 4, 2013 by Wang, Hoderlein, Lebens, Yau, and Trauernicht), the disclosures of all of which are incorporated herein by reference.

Once the conductive composition has been added to the micro-channels, the conductive materials or the pattern of conductive micro-wires can be further cured using light, heat (at least ° C.), or a reagent including for example a vapor or a liquid composition (such as an acid vapor) to form the conductive micro-wires. The curing or heating can drive off solvent(s) from the conductive composition and can also sinter metal nanoparticles if desired.

In one embodiment, the conductive composition (ink) for the practice of the present invention is a metal nanoparticle composition comprising water, a water-soluble polymer, and silver nanoparticles having a mean size of from 5 to 150 nm, wherein the weight percentage of silver nanoparticles in the conductive composition is greater than 10 weight % of the total conductive composition weight.

Thus, the resulting conductive micro-wires can be designed to have a cross-sectional average width of less than or equal to 20 μm or more likely less than 10 μm and as small as 0.5 μm. The average width can be determined by averaging the measured width of at least 10 different micro-wires. The average depth of the micro-wire can be the same as or different from the average micro-wire width and is generally determined by the depth of the micro-channels.

It is also possible to enhance the conductivity of conductive composition in the micro-channels in various ways, for example by exposing conductive metal nanoparticles (such as silver nanoparticles) to a halide in liquid or gaseous form. Thus, such a treatment can be carried out using a halide compound such as sodium chloride, potassium chloride, hydrogen chloride, calcium chloride, magnesium chloride, sodium bromide, potassium bromide, hydrogen bromide and other compounds readily apparent to one skilled in the art. In addition, the treatment can be carried out by using a vapor source such as hydrochloric acid vapor at room temperature. Alternatively, the halide treatment can be provided by an inorganic halide (such as calcium chloride) or halide-containing polymer that is coated onto or part of the substrate.

It is also possible to enhance conductivity of certain components of the conductive composition (such as silver nanoparticles) by applying heat to the conductive composition in the micro-channels. Further details of this process are provided for example in copending and commonly assigned U.S. Ser. No. 13/759, 899 (filed Feb. 4, 2013 by Wang, Hoderlein, Lebens, Yau, and Trauernicht) the disclosure of which is incorporated herein by reference.

Thus, the method of the present invention can be used to prepare a patterned article comprising pattern of cured micro-channels. Such electrically conductive articles can comprise the pattern of conductive micro-wires such as conductive micro-wires composed of silver nanoparticles, and they can be incorporated into various devices such as touch screen displays or panels such as projected-capacitive touch screens that use transparent micro-wire electrodes and other touch screen displays, light-liquid crystal or organic light-emitting diode displays. Electrically conductive micro-wires can be located in areas of a device other than the display areas, for example in the perimeter of the display area of a touch screen panel.

Further details about forming micro-wires and their uses can be found in copending and commonly assigned U.S. Ser. Nos. 13/746,346 and 13/746,352 (both filed Jan. 22, 2013 by Trauernicht, Lebens, and Wang), the disclosures of both of which are incorporated herein by reference.

The present invention provides at least the following embodiments and combinations thereof, but other combinations of features are considered to be within the present invention as a skilled artisan would appreciate from the teaching of this disclosure:

1. A photocurable composition comprising:

a compound that generates an acid upon exposure to radiation of at least 190 nm and up to and including 500 nm,

a multifunctional epoxy compound having an epoxy equivalent molecular weight of less than 1,000, and

an epoxysilane oligomer that is represented by the following Structure (1):

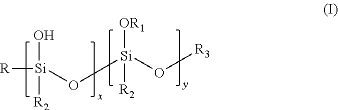

wherein R and R₁ are independently substituted or unsubstituted alkyl groups, R₂ is a substituted or unsubstituted linear, branched, or cyclic alkyl group or an alkyl ether residue substituted with an epoxide, R₃ is hydrogen or a substituted or unsubstituted alkyl, and x+y≧2.

2. The photocurable composition of embodiment 1, wherein R and R₁ are independently unsubstituted alkyl groups or substituted or unsubstituted arylalkyl groups, R₂ is an unsaturated linear, branched, or cyclic alkyl group or an alkyl ether group, and R₃ is hydrogen or an unsubstituted alkyl group or an unsubstituted arylalkyl group.

3. The photocurable composition of embodiment 1 or 2, wherein the sum of x and y is at least 3.

4. The photocurable composition of any of embodiments 1 to 3, wherein the multifunctional epoxy compound to the epoxysilane oligomer weight ratio is from 9:1 and to and including 1:9.

5. The photocurable composition of any of embodiments 1 to 4, wherein the compound that generates an acid is present in an amount of at least 0.1 weight % and up to and including 20 weight %, based on total photocurable composition solids.

6. The photocurable composition of any of embodiments 1 to 5, wherein the multifunctional epoxy compound is present in an amount of at least 30 weight % and up to and including 90 weight %, based on total photocurable composition solids.

7. The photocurable composition of any of embodiments 1 to 6, further comprising a photosensitizer.

8. The photocurable composition of any of embodiments 1 to 7, wherein the multifunctional epoxy compound has a softening point of 20° C. or more, and the epoxysilane oligomer has a softening point less than or equal to 20° C.

9. The photocurable composition of any of embodiments 1 to 8, wherein the acid generating compound is an onium salt of a Group V-A element, an onium salt of a Group VI-A element, or an aromatic halonium salt.

10. The photocurable composition of any of embodiments 1 to 9, wherein the multifunctional epoxy compound is represented by the following Structure (II):

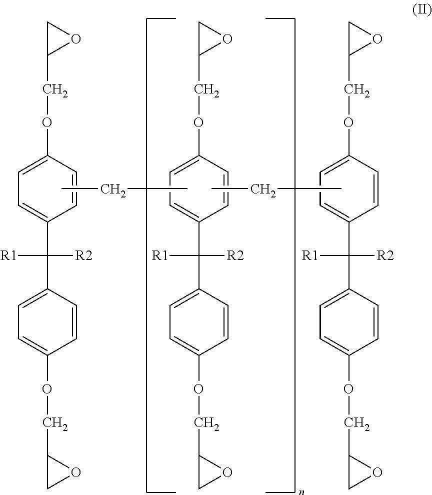

wherein R1 and R2 are independently hydrogen or methyl, and n is 0 or a positive integer.

11. The photocurable composition of any of embodiments 1 to 10, further comprising one or more of an adhesion promoter, glycidyl ether reactive monomer, filler, lubricant, colorant, rheology modifier, humectants, coating surfactant, matting agent, or non-conductive particle.

12. A photocurable article comprising a substrate and having thereon a dry photocurable layer comprising the photocurable composition of any of embodiments 1 to 11.

13. The photocurable article of embodiment 12, wherein the substrate comprises a transparent material, metal-containing material, fabric, or ceramic material.

14. A method for forming a conductive element, comprising:
providing the photocurable article of embodiment 12 or 13,
forming a pattern of micro-channels within the photocurable composition of the photocurable article, and
exposing the photocurable composition to form a patterned article comprising a pattern of cured micro-channels.

15. The method of embodiment 14, further comprising:

filling the pattern of cured micro-channels with a conductive composition to form a pattern of conductive micro-wires.

16. The method of embodiment 14 or 15, comprising forming the pattern of micro-channels using an imprinting mold, which imprinting mold is removed from the pattern of cured micro-channels after the exposing feature and before the filling feature.

17. The method of any of embodiments 14 to 16, wherein the micro-channels have an average aspect ratio (width to depth) greater than 0.1 and up to and including 10, and an average width of at least 0.5 μm and up to and including 5 μm.

18. The method of any of embodiments 15 to 17, wherein the conductive composition comprises silver nanoparticles in an amount greater than 10 weight % of the total conductive composition dry weight.

19. A patterned article comprising pattern of cured micro-channels provided by the method of any of embodiments 14 to 18.

20. An electrically conductive article comprising a pattern of conductive micro-wires provided by the method of any of embodiments 15 to 18.

The following Examples are provided to illustrate the practice of this invention and are not meant to be limiting in any manner. The following materials were used in the Examples:

Coatosil MP-200 is an epoxysilane oligomer that was obtained from Momentive Performance Materials.

SU-8 3000 is a multifunctional epoxy compound that was obtained from Mementive Performance Materials.

### Invention Examples 1-3

### Photocurable Compositions and Forming Patterned Articles Using Photo-imprinting Lithography

A poly(ethylene terephthalate) film having a dry thickness of about 125 μm had been surface coated with a poly(vinylidene chloride) containing latex to form an adhesion promotion subbing layer. Each of the coating formulations having the components described below (in weight %) in TABLE I was applied over the adhesion promotion subbing layer and dried to form photocurable compositions, each having a nominal dry thickness of about 5.5 μm. The resulting Control photocurable article Al and Invention photocurable articles B1 through D1 (Invention Examples 1-3) were prepared. Control photocurable article A1 was prepared using a photocurable composition similar to that disclosed in prior art, that is, containing the SU-8 3000 resin.

TABLE I

| | | B1 | C1 | D1 |
|---|---|---|---|---|
| | A1 | (Invention | (Invention | (Invention |
| | (Control) | Example 1) | Example 2) | Example 3) |
| SU-8 3000 resin | 40 | 34 | 28 | 20 |
| Coatosil MP-200 | 0 | 6 | 12 | 20 |
| Triarylsulfonium | 4.8 | 4.8 | 4.8 | 4.8 |
| hexafluoro- | | | | |
| phosphate | | | | |
| mixed salts | | | | |
| (50% in | | | | |
| propylene | | | | |
| carbonate) | | | | |
| Methyl ethyl | 55.2 | 55.2 | 55.2 | 55.2 |
| ketone | | | | |

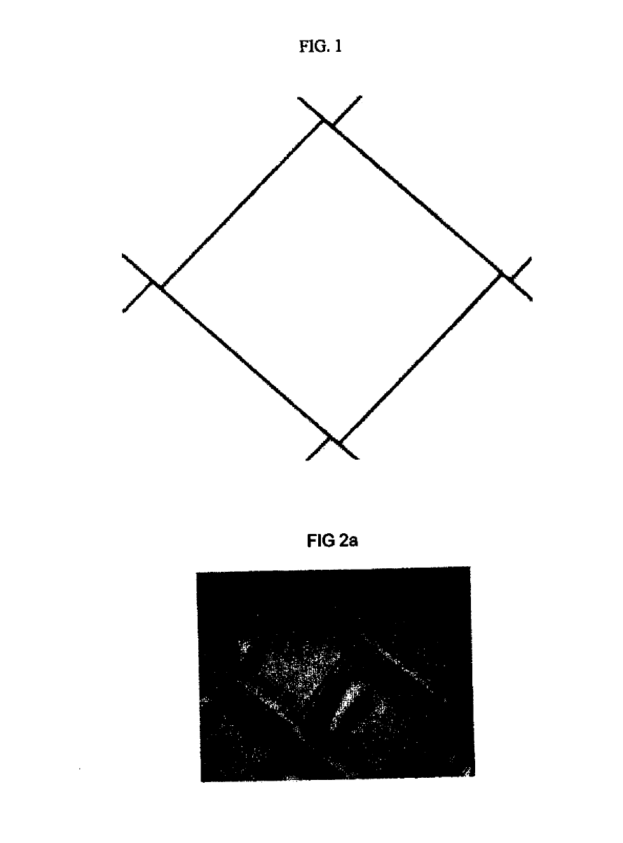

The dry photocurable layer of each of the articles was pressed against a transparent elastomeric mold made from Dow Corning Sylgard 184 siloxane elastomer at 90° C. for about 3 minutes at 5 psi (0.034 megaPascals) and 2 minutes at 25 psi (0.17 megaPascals) followed by exposure to ultraviolet light to cure the dry photocurable layer in each article. The mold surface contained a diamond line pattern of 600 μm by 540 μm. For example, FIG. 1 shows a single diamond pattern of the mold surface with side 1 and side 3 being rotated by +/−9.42 μm or about 2.66 degrees; the side lengths are 402 μm for sides 1 and 3, and 403.6 μm for sides 2 and 4; both line width and height were 4 μm; and line filling fraction of about 2%. The mold surface with the diamond patterns was pressed against each dry photocurable layer.

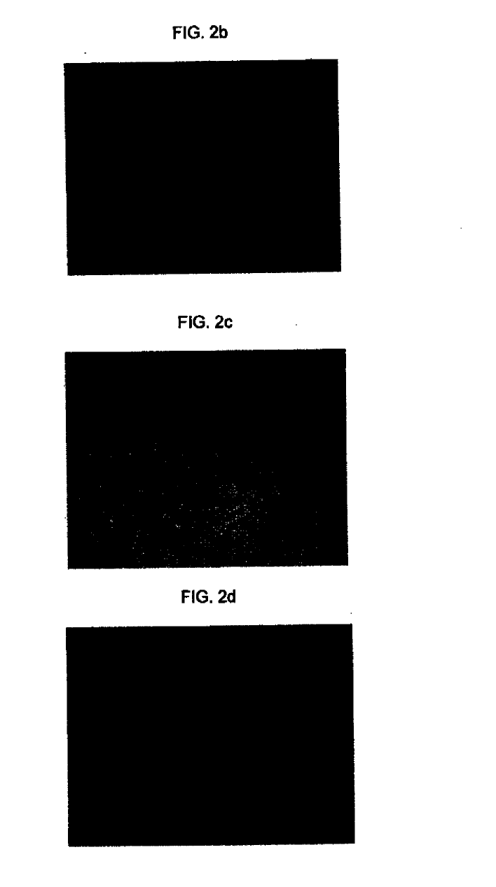

After the UV light exposure, the elastomeric mold was separated from each article to leave imprints in the photocurable layer having the aforementioned diamond line patterns except that the diamond line patterns were now made of micro-channels having both width and depth of about 4 μm. The photocured and patterned surface of the each article was examined under an optical microscope. As shown in the photomicrographs of FIGS. 2b through 2d, excellent photocured patterns were obtained for the articles of Invention Examples 1-3, respectively. However, FIG. 2a shows the poor results of photocuring and photo-imprint lithography of the Control article (made using su-8 3000 resin).

The photo-imprinting process was repeated with another sample of Invention Example 3 but it was carried out at various temperatures from room temperature (20° C.) to 60° C. under 5 psi (0.034 megaPascals) pressure for 3 minutes. Excellent photo-imprints in the resulting patterned articles were obtained at all temperatures.

### Comparative Example 1

Comparative Example 1 was obtained by applying, under pressure with a roller at room temperature, a photocurable liquid composition between the transparent elastomeric mold described above and a poly(ethylene terephthalate) (PET) film having a thickness of about 125 μm that had been surface coated with a poly(vinylidene chloride) containing latex. A liquid photocurable composition was made by mixing Coatosil MP-200 and a photoinitiator composition containing mixed triarylsulfonium hexafluorophosphate salts (50% in propylene carbonate). The roller was rolled on the top of the transparent elastomeric mold (opposite to the surface that contains the imprinting pattern) such that the liquid photocurable composition formed a bead advancing between the PET and the transparent elastomeric mold to form a sandwich structure. The mold surface pressing against the liquid photocurable composition contained the imprinting pattern.

After being pressed together, the sandwich structure was irradiated with UV light at room temperature followed by a heating step at 90° C. for 2 minutes, to cure the photocurable composition. After the transparent elastomeric mold was separated from the resulting imprinted film, the surface of the imprinted pattern was examined visually and found to contain numerous air bubbles.

### Invention Example 4

### Electrically Conductive Article

Photocurable composition B1 described above in TABLE I and used in Invention Example 1, containing about 42.4% solids was used to form a dry film having a thickness of about 12 μm by coating the photocurable composition onto a transparent poly(ethylene terephthalate) film. The resulting dry film photoresist surface was then laminated with a protective sheet of approximately 25.4 μm thick having one of its surfaces treated with a silicone release coating so that the protective sheet can be separated readily from the dry film photoresist surface.

The dry film photoresist was then used make an imprint pattern in a similar manner to that described above in Invention Example 1. The transparent elastomeric mold used contained 16 measurement cells. Each measurement cell was about 102.3 mm long and 3.78 mm wide and was made with the connected diamond structure shown in FIG. 1. Therefore each measurement cell was about 170.5 diamond patterns long and 7 diamond patterns wide. The resulting pattern lines were 4 μm wide and 4 μm high.

The resulting photo-imprint was then filled with an aqueous conductive composition (ink) comprising about 75 weight % of silver nanoparticles having a mean particle size of about 73 nm, 0.75 weight % of poly(vinylidene chloride-co-ethyl acrylate-co-acrylic acid) (85/14/1) latex, and 0.34 weight % of a carbon black dispersion having a mean carbon black particle size of about 120 nm. The silver nanoparticles were prepared in accordance with the method described in copending and commonly assigned U.S. Ser. No. 13/757,891 (noted above). Excess quantities of conductive composition on the dry film photoresist surface were removed using a wiper. The wiping was conducted in such a fashion that most of the applied conductive composition on the surface was removed without disturbing the conductive composition left in the micro-channels. The filled imprinted pattern was dried at room temperature, treated with saturated hydrochloric acid vapor for 2 minutes, polished with a wet cloth, and cured further at 90° C. for 2 minutes.

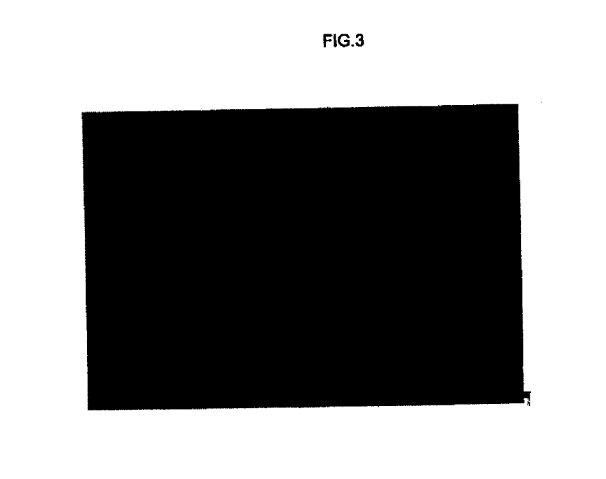

The resulting transparent electrode (electrically conductive article) showed excellent micro-wire uniformity without any significant distortion of the support structure (as shown in FIG. 3). It had a surface resistivity of less than 6 ohms/sq, 87% light transmission without lamination to glass with an anti-reflection coating, and a haze value of about 0.95%. The resulting transparent electrode was also tested for adhesion, scratch resistance, and cyclic bending. It showed excellent performance in all of these evaluations.

The invention has been described in detail with particular reference to certain preferred embodiments thereof, but it will be understood that variations and modifications can be effected within the spirit and scope of the invention.

1. A photocurable composition comprising:
a compound that generates an acid upon exposure to radiation of at least 190 nm and up to and including 500 nm,
a multifunctional epoxy compound having an epoxy equivalent molecular weight of less than 1,000, and
an epoxysilane oligomer that is represented by the following Structure (I): 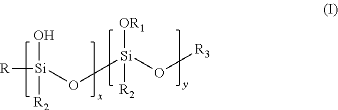
wherein R and R₁ are independently substituted or unsubstituted alkyl groups, R₂ is a substituted or unsubstituted linear, branched, or cyclic alkyl group or an alkyl ether residue substituted with an epoxide, R₃ is hydrogen or a substituted or unsubstituted alkyl, and x+y≧2.

2. The photocurable composition of claim 1, wherein R and R₁ are independently unsubstituted alkyl groups or substituted or unsubstituted arylalkyl groups, R₂ is an unsaturated linear, branched, or cyclic alkyl group or an alkyl ether group, and R₃ is hydrogen or an unsubstituted alkyl group or an unsubstituted arylalkyl group.

3. The photocurable composition of claim 1, wherein the sum of x and y is at least 3.

4. The photocurable composition of claim 1, wherein the multifunctional epoxy compound to the epoxysilane oligomer weight ratio is from 9:1 and to and including 1:9.

5. The photocurable composition of claim 1, wherein the compound that generates an acid is present in an amount of at least 0.1 weight % and up to and including 20 weight %, based on total photocurable composition solids.

6. The photocurable composition of claim 1, wherein the multifunctional epoxy compound is present in an amount of at least 10 weight % and up to and including 90 weight %, based on total photocurable composition solids.

7. The photocurable composition of claim 1, further comprising a photosensitizer.

8. The photocurable composition of claim 1, wherein the multifunctional epoxy compound has a softening point of 20° C. or more, and the epoxysilane oligomer has a softening point less than or equal to 20° C.

9. The photocurable composition of claim 1, wherein the acid generating compound is an onium salt of a Group V-A element, an onium salt of a Group VI-A element, or an aromatic halonium salt.

10. The photocurable composition of claim 1, wherein the multifunctional epoxy compound is represented by the following Structure (II): 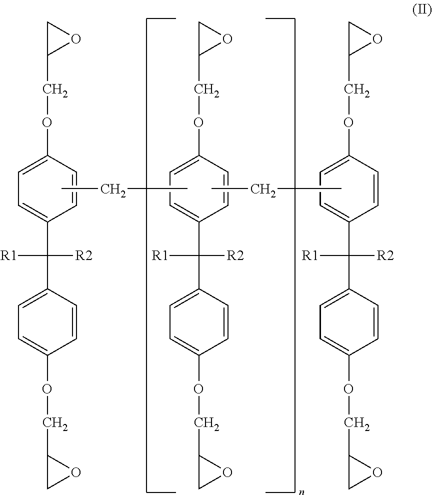
wherein R1 and R2 are independently hydrogen or methyl, and n is 0 or a positive integer.

11. The photocurable composition of claim 1, further comprising one or more of an adhesion promoter, glycidyl ether reactive monomer, filler, lubricant, coating surfactant, matting agent, or conductive particle.

12. A photocurable article comprising a substrate and having thereon a dry photocurable layer comprising the photocurable composition of claim 1.

13. The photocurable article of claim 12, wherein the substrate comprises a transparent material, metal-containing material, fabric, or ceramic material.

14. A method for forming a conductive element, comprising:
providing the photocurable article of claim 12,
forming a pattern of micro-channels within the photocurable composition of the photocurable article, and
exposing the photocurable composition to form a patterned article comprising a pattern of cured micro-channels.

15. The method of claim 14, further comprising:
filling the pattern of cured micro-channels with a conductive composition to form a pattern of conductive micro-wires.

16. The method of claim 14, comprising forming the pattern of micro-channels using an imprinting mold, which imprinting mold is removed from the pattern of cured micro-channels after the exposing feature and before the filling feature.

17. The method of claim 14, wherein the micro-channels have an average aspect ratio (width to depth) greater than 0.1 and up to and including 10, and an average width of at least 0.5 μm and up to and including 5 μm.

18. The method of claim 15, wherein the conductive composition comprises silver nanoparticles in an amount greater than 10 weight % of the total conductive composition dry weight.

19. A patterned article comprising pattern of cured micro-channels provided by the method of claim 14.

20. An electrically conductive article comprising a pattern of conductive micro-wires provided by the method of claim 15.
